(19) United States
(12) Patent Application Publication
(10) Pub. No.: US 2014/0160662 A1
(43) Pub. Date: Jun. 12, 2014

(54) BRACKET OF ADD-IN CARD OF COMPUTER, ADD-IN CARD SYSTEM AND COMPUTER

(71) Applicant: NVIDIA CORPORATION, Santa Clara, CA (US)

(72) Inventors: Zhi Li, Guangdong (CN); Qiang CHEN, Guangdong (CN); Charlie J. Shu, Santa Clara, CA (US)

(73) Assignee: NVIDIA CORPORATION, Santa Clara, CA (US)

(21) Appl. No.: 13/722,408

(22) Filed: Dec. 20, 2012

(30) Foreign Application Priority Data
Dec. 7, 2012 (CN) 201210524153.7

(51) Int. Cl. H05K 7/14

(52) U.S. Cl. CPC H05K 7/1435
USPC 361/679.32; 361/753

(57) ABSTRACT

A bracket of an add-in card of an electronic device is provided. The bracket, in one embodiment, includes a body in a shape of a sheet, wherein the body is provided with an opening, the opening configured to correspond to an interface adapter on the add-in card and expose an interface part of the interface adapter in an installed state when the bracket is installed to the add-in card. The bracket, in this embodiment, further includes a conductive component in electrical connection with the body, the conductive component configured to electrically connect with a housing of the interface adapter in the installed state, wherein at least a portion of the body is made of a conductive material so that the conductive component is electrically connected with a chassis via the body when installed.

### CROSS-REFERENCE TO RELATED APPLICATIONS

This application claims priority to Chinese Patent Application No. 201210524153.7, filed on Dec. 7, 2012, to Zhi Li, et al. to which is hereby incorporated by reference in its entirety.

### TECHNICAL FIELD

The present disclosure relates generally to the electricity technology, in particular, to a bracket of an add-in card of a computer, an add-in card with the bracket and a computer with the add-in card.

### BACKGROUND

At present, in order to prevent data transmission from being disturbed and ensure the fluency of data transmission, many interface adapters, such as HDMI (High Definition Multimedia Interface) interface adapter and DP (Display Port) interface adapter, etc., are usually provided with metal housings. The metal housings are grounded such that they can act as the shielding layers.

FIG. 1 illustrates an interface adapter 100 of the prior art. As shown in FIG. 1, in order to ground a housing 110 of the interface adapter 100, a conductive gasket 130 extending towards the outside of the interface part 120 is disposed at the edge of the interface part 120 of the interface adapter 100. The conductive gasket 130 is fixed to the housing 110 of the interface adapter 100 by wrapping a metal sheet 140. When the interface adapter 100 is installed to an add-in card and then the add-in card is installed to a computer, the conductive gasket 130 of the interface adapter 100 is electrically connected with the chassis of the computer, and thus the housing 110 of the interface adapter 100 is grounded through the chassis.

However, the aforementioned grounding manner leads to a complex structure of the interface adapter and brings much inconvenience to the installation of the interface adapter. Therefore, there is a need of providing a bracket of an add-in card of a computer, an add-in card with the bracket and a computer with the add-in card to solve the above problem in the prior art.

### SUMMARY

In order to solve the above problem, according to one aspect of the disclosure, a bracket of an add-in card of an electronic device is provided. The bracket, in one embodiment, includes a body in a shape of a sheet, wherein the body is provided with an opening, the opening configured to correspond to an interface adapter on the add-in card and expose an interface part of the interface adapter in an installed state when the bracket is installed to the add-in card. The bracket, in this embodiment, further includes a conductive component in electrical connection with the body, the conductive component configured to electrically connect with a housing of the interface adapter in the installed state, wherein at least a portion of the body is made of a conductive material so that the conductive component is electrically connected with a chassis via the body when installed.

According to another aspect of the disclosure, an add-in card system of an electronic device is provided. The add-in card system, in one embodiment, includes an add-in card provided with an interface adapter, as well as a bracket coupled to one end of the add-in card. The bracket, in this embodiment, includes a body in a shape of a sheet, wherein the body is provided with an opening, the opening corresponding to the interface adapter of the add-in card and exposing an interface part of the interface adapter. The bracket, in this embodiment, further includes a conductive component in electrical connection with the body, the conductive component electrically connected with a housing of the interface adapter, wherein at least a portion of the body is made of a conductive material so that the conductive component is electrically connected with a chassis of an electronic device via the body.

According to yet another aspect of the disclosure, a computer is provided. The computer, in one embodiment, includes: 1) a chassis with an add-in card installing port provided thereon, 2) an add-in card provided with an interface adapter, and 3) a bracket coupled to one end of the add-in card, the add-in card installed to the chassis through the bracket and the add-in card installing port is covered by the bracket. The bracket, in this embodiment, includes a body in a shape of a sheet, wherein the body is provided with an opening, the opening corresponding to the interface adapter of the add-in card and exposing an interface part of the interface adapter, as well as a conductive component in electrical connection with the body, the conductive component electrically connected with a housing of the interface adapter, wherein at least a portion of the body is made of a conductive material so that the conductive component is electrically connected with a chassis of an electronic device via the body.

The bracket of the add-in card of the computer provided by the disclosure enables the housing of the interface adapter to be grounded, and thus the structure of the interface adapter is simplified and the manufacturing cost of the interface adapter is reduced. Moreover, in the installing process, the electrical connection between the conductive component and the interface adapter may be achieved just by contacting the conductive component with the housing of the interface adapter directly or through other conductive means. Consequently, it has the advantages, such as the convenience of installation and the stability of connection, etc.

A serial of simplified conceptions are incorporated into the summary, which will be further described in more detail in the detailed description. The summary neither implies that it is intended to limit the essential features and necessary technical features of the technical solution to be protected, nor implies that it is intended to define the protection scope of the technical solution to be protected.

### BRIEF DESCRIPTION OF THE DRAWINGS

Reference is now made to the following descriptions taken in conjunction with the accompanying drawings, in which:

FIG. 1 is a schematic view of a interface adapter in the prior art;

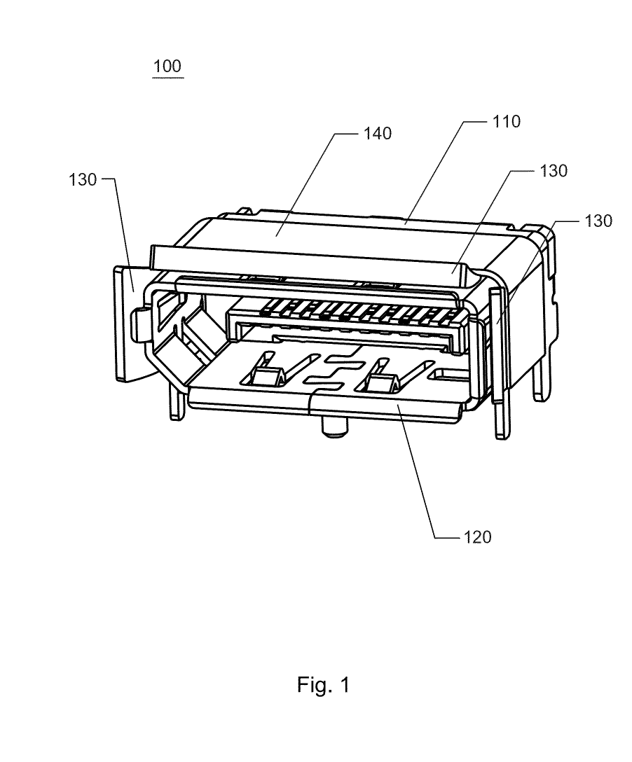

FIG. 2 is a schematic view of a bracket of an add-in card of a computer according to one embodiment of the disclosure; and

FIG. 3 is a schematic view of an add-in card according to one embodiment of the disclosure, wherein a bracket of an add-in card of a computer is connected to one end thereof.

### DETAILED DESCRIPTION

Many specific details are presented so as to provide more thoroughly understanding of the present disclosure in the description below. However, the present disclosure may be implemented without one or more of these details, as is obvious to those skilled in the art. In other examples, some of the technical features known in the art are not described so as to avoid confusions with the present disclosure.

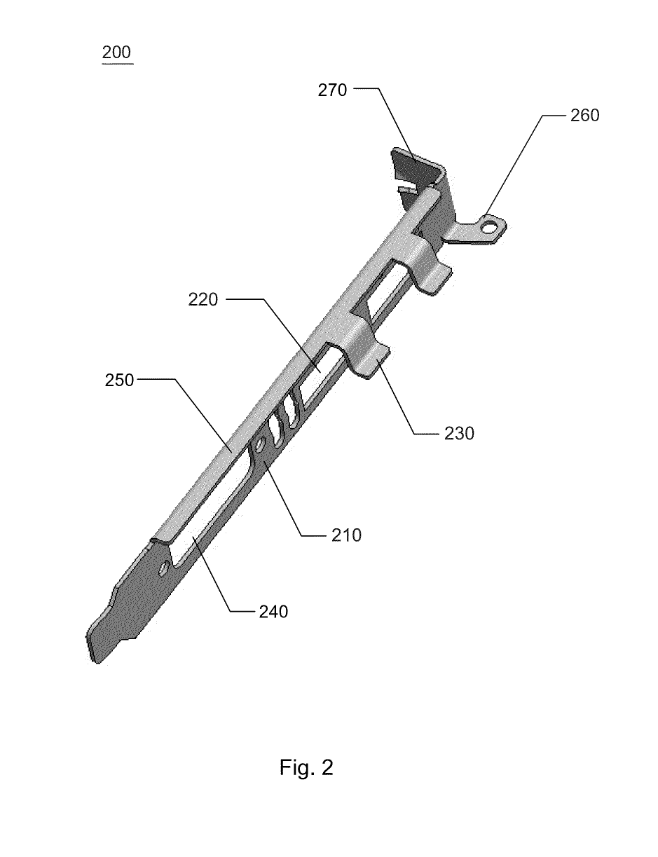

According to one aspect of the disclosure, a bracket of an add-in card of a computer (hereinafter referred to as the bracket) is provided. FIG. 2 illustrates the bracket 200 according to one embodiment of the disclosure. The bracket 200 will be described in detail below with reference to FIG. 2.

As shown in FIG. 2, the bracket 200 comprises a body 210 in the shape of a sheet. The body 210 is provided with an opening 220, and the opening 220 is corresponding to the interface adapter (not shown) on the add-in card (not shown) in the installed state that the bracket 200 is installed to the add-in card. Moreover, the opening 220 extends at least partially from one side to the other side of the body 210 to expose the interface part of the interface adapter in the installed state that the bracket 200 is installed to the add-in card. The quantity and the position of the opening 220 may be corresponding to those of the interface adapter on the add-in card, so as to expose the corresponding interface adapter in the installed state. The size of the opening 220 may be corresponding to that of the interface part of the interface adapter to fit the opening 220 for the interface part of the interface adapter precisely in the installed state. It will be understood that the quantity, position and size of the opening 220 illustrated in FIG. 2 are just exemplary, which are not used to limit the present disclosure. If the add-in card is also provided with other interface adapters or other devices, which require exposing a part thereof, the body may be provided with one or more other openings 240. In addition, the body 210 can also be provided with the fixing holes and/or heat-dissipating holes, etc. for fixing the interface adapter or other means as needed.

The body 210 is provided with a conductive component 230, which may be formed with the body 210 integrally or separately. The conductive component 230 is electrically connected with the housing of the interface adapter in the installed state that the bracket 200 is installed to the add-in card. At least a portion of the body 210 is made of a conductive material (such as a metal material), such that the conductive component 230 can be electrically connected with the chassis of the computer via the body 210 when the add-in card with the bracket 200 installed thereon is installed to the computer. In this embodiment, the interface adapter is grounded through the bracket 200 and the chassis. The conductive component 230 may be disposed around the opening 220. As an example, the conductive component 230 may be disposed above the opening 220. The conductive component 230 is connected to the body 210 above the opening 220 and extends downwards to be electrically connected with the housing of the interface adapter in the installed state. As an example, the conductive component 230 may also be disposed at the side of the opening 220. The conductive component 230 is connected to the body 210 at the middle of the body 210 and extends towards the opening 200 to be electrically connected with the housing of the interface adapter in the installed state. Those skilled in the art can suitably arrange the position of the conductive component 230 as appropriate. In the installing process, the electrical connection can be achieved just by contacting the conductive component 230 with the housing of the interface adapter directly or through other conductive means. It is easy to achieve in the installing process.

When the body 210 is provided with a plurality of openings 220, the quantity of the conductive component(s) 230 may be more than, equal to or less than that of the opening 220. That is, a plurality of openings 220 may share one conductive component 230, one opening 220 may be distributed with a plurality of the conductive components 230, one opening 220 may be corresponding to one conductive component 230, or several of the above-mentioned cases may exist together. It is simply required that the housing of each interface adapter is electrically connected with the corresponding conductive component 230 in the installed state. As an example, when the body 210 is provided with a plurality of openings 220 and only one conductive component 230, the conductive component 230 may be disposed above the plurality of openings 220. The conductive component 230 may extend from the area above the first opening 220 to the area above the last opening 220, such that the conductive component 230 may be electrically connected with the housings of the interface adapters simultaneously in the installed state. As an example, when the quantity of the conductive component(s) 230 is less than that of the openings 220, one conductive component 230 may be disposed between the two adjacent openings 220. Those skilled in the art can suitably configure the conductive component(s) 230 as appropriate.

Preferably, when the body 210 is provided with a plurality of openings 220, a plurality of conductive components 230 may be disposed, with each opening 220 corresponding to each conductive component 230. It can improve the stability of the connection between the conductive component 230 and the interface adapter in the installed state by distributing multiple conductive components 230 for each opening 220. However, as for the present manufacturing process, the difficulty of the process may be increased and the manufacturing cost may be enhanced. It may simplify the structure of the bracket 200 when a plurality of openings 220 share one conductive component 230, but it may be restricted in the case that different types of the interface adapters leads to different heights thereof. Consequently, it has not only a wider application range but also a relatively simpler manufacturing process by disposing one conductive component 230 with one corresponding opening 220.

According to one embodiment of the disclosure, a reinforced edge 250 angled with respect to the body 210 is disposed on the top of the body 210. As the body 210 is in the shape of a sheet, it is prone to deform when receiving an external force. The strength of the bracket 200 may be improved through disposing the reinforced edge 250 on the top of the body 210. The reinforced edge 250 may be perpendicular to the body 210, or angled with respect to the body 210 at other angles. The reinforced edge 250 may be any member that is able to improve the strength of the bracket 200. The reinforced edge 250 may be continuously disposed on the top of the body 210 as illustrated in FIG. 2, or may also be discontinuously disposed on the top of the body 210. In addition, the length of the reinforced edge 250 relative to the body 210 may also be chosen as appropriate. It should be noted that the conductive component 230 might be connected to the reinforced edge 250 (as shown in FIG. 2) or other positions of the body 210 when the reinforced edge 250 is disposed on the top of the body 210.

Preferably, the conductive component 230 is an elastic component so that the conductive component 230 elastically presses against the housing of the interface adapter in the installed state. In this way, the stability of the electrical connection between the housing of the interface adapter and the conductive component 230 is enhanced, and the convenience of the installation is improved. The elasticity of the conductive component 230 may be produced by the material of the conductive component 230. The selected material should also have a good conductive performance. The elasticity of the conductive component 230 may also be produced by suitably choosing the structure thereof, such as a structure similar to the spring, etc.

According to another embodiment of the disclosure, the conductive component 230 is substantially in the shape of Z. One end (the first end) of the conductive component 230 is connected to the body 210 above the opening 220, and the other end (the second end) of the conductive component 230 is used for being electrically connected with the housing of the interface adapter. In this way, the conductive component 230 may extend downwards from the area above the opening 220, so as to be electrically connected to the housing of the interface adapter in the installed state. The first end of the conductive component 230 may be connected to the top of the body 210, while the second end of the conductive component 230 is free in the un-installed state and is against the top wall of the housing of the interface adapter in the installed state. The “Z” structure can increase the contacting area between the second end of the conductive component 230 and the housing of the interface adapter, and also can restrain the movement of the second end of the conductive component 230 in the direction away from the interface adapter when the conductive component 230 is applied an external force. Therefore, it ensures the stability of the connection between the conductive component 230 and the interface adapter. In addition, the conductive component 230 can have some elasticity through suitably choosing the thickness of the material manufacturing the conductive component 230, such that the convenience of the installation can be improved and the stability of the electrical connection can be enhanced

Preferably, one end of the body 210 may be provided with an add-in card fixing element 260. The add-in card fixing element 260 and the conductive component 230 are disposed on the same side of the body 210 in one embodiment. When it is installed to the computer, the side including the fixing element 260 typically faces the interior of the chassis. The add-in card fixing element 260 is used for fixing the bracket 200 to the add-in card, such as, the PCB board of the add-in card. As an example, the add-in card fixing element 260 may include a fixing board extending from the bottom of the body 210 in the direction perpendicular to the body 210 and a fixing hole disposed on the fixing board, such that the bracket 200 may be detachably installed to the add-in card through the fastener, such as, the screw, etc. Alternatively, the add-in card element 260 may also have other structures that can install the bracket 200 to the add-in card. The special add-in card fixing element 260 for fixing the bracket 200 to the add-in card can achieve the convenient installation and the steady connection. In addition, the bracket 200 may be fixed to the add-in card through welding, adhering, etc. The present disclosure is not intended to exclude the connecting manners from the protection scope of the disclosure.

One end of the body 210 may be provided with a chassis fixing element 270. The chassis fixing element 270 and the conductive component 230 are disposed on the opposite sides of the body 210. When it is installed to the computer, the side of the chassis fixing element 270 faces the exterior of the chassis. The chassis fixing element 270 is used for fixing the bracket 200 to the chassis. As an example, the chassis fixing element 270 may include a fixing board extending from the end of the body 210 in the direction perpendicular to the body 210 and a fixing slot disposed on the fixing board, such that the bracket 200 may be detachably installed to the chassis through the screw. Alternatively, the chassis fixing element 270 may also have other structures that can install the bracket 200 to the chassis. The special chassis fixing element 270 for fixing the bracket 200 to the chassis can achieve the convenient installation and the steady connection.

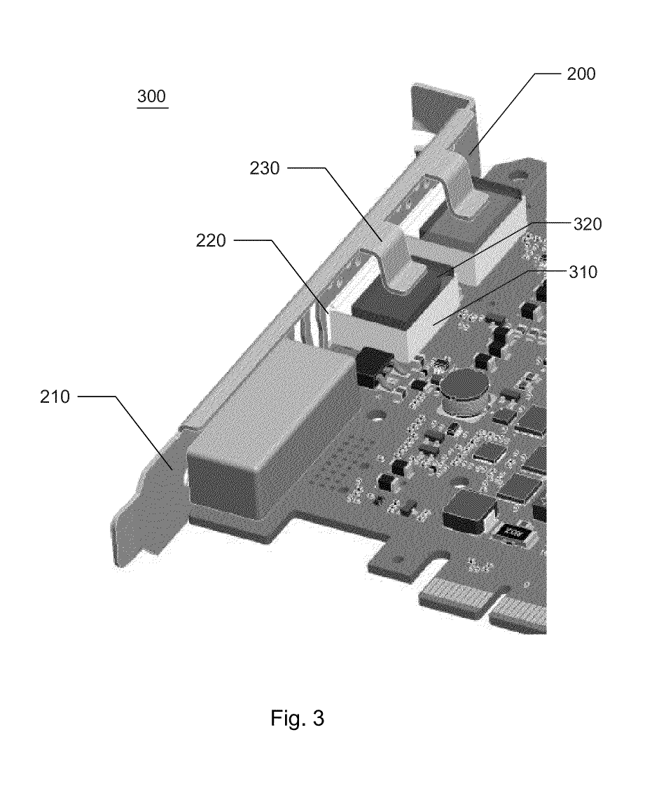

According to another aspect of the disclosure, an add-in card 300 of a computer (hereinafter referred to as the add-in card 300) is provided, as shown in FIG. 3. The add-in card 300 is provided with an interface adapter 310, which may be any interface adapter with a metal housing, such as HDMI interface adapter, DP interface adapter, USB interface adapter and/or RJ45 interface adapter, etc. The add-in card 300 may be a graphics card and/or a network card, etc. A bracket 200 is installed to one end of the add-in card 300. The bracket 200 has any structure as described before. That is, the bracket 200 comprises a body 210 in the shape of a sheet, the body 210 is provided with an opening 220, the opening 220 is corresponding to the interface adapter 310 and exposes the interface part (not shown) of the interface adapter 310. The body 210 is provided with a conductive component 230. The conductive component 230 is electrically connected with the housing of the interface adapter 310, and at least a portion of the body 210 is made of a conductive material so that the conductive component 230 is electrically connected with a chassis via the body 210. Each component included by the bracket 200 can be referred to the corresponding description mentioned before, which is no longer described in detail.

Preferably, a flexible conductive enhancing element 320 is disposed between the conductive component 230 and the housing of the interface adapter 310. The conductive enhancing element 320 may be a conductive gasket or a conductive fabric, etc. When the conductive component 230 and/or the interface adapter 310 abut against the flexible conductive enhancing element 320, the contacting area between them may be magnified. In this way, a super low impedance path is formed between the conductive component 230 and the interface adapter 310, and thus the Electro Magnetic Compatibility (EMC) is improved.

According to yet another aspect of the disclosure, a computer is provided. The computer comprises a chassis and any add-in card as mentioned above. The chassis is provided with an add-in card installing port. A bracket (referring to FIG. 3) is installed to one end of the add-in card. The add-in card is installed to the chassis through the bracket and the bracket covers the add-in card installing port.

The bracket of the add-in card of the computer provided by the disclosure enables the housing of the interface adapter to be grounded, and thus the structure of the interface adapter is simplified and the manufacturing cost of the interface adapter is reduced. Moreover, in the installing process, the electrical connection between the conductive component and the interface adapter may be achieved just by contacting the conductive component with the housing of the interface adapter directly or through other conductive means. Consequently, it has the advantages, such as the convenience of installation and the stability of connection, etc.

The present disclosure has been described by the above-mentioned embodiments. However, it will be understood that the above-mentioned embodiments are for the purpose of demonstration and description and not for the purpose of limiting the present to the scope of the described embodiments. Moreover, those skilled in the art could appreciate that the present disclosure is not limited to the above-mentioned embodiments and that various modifications and adaptations in accordance of the teaching of the present disclosure may be made. The protection scope of the present disclosure is further defined by the following claims and equivalent scope thereof.

What is claimed is:

1. A bracket of an add-in card system of an electronic device, comprising:
a body in a shape of a sheet, wherein the body is provided with an opening, the opening configured to correspond to an interface adapter on the add-in card and expose an interface part of the interface adapter in an installed state when the bracket is installed to the add-in card; and
a conductive component in electrical connection with the body, the conductive component configured to electrically connect with a housing of the interface adapter in the installed state, wherein at least a portion of the body is made of a conductive material so that the conductive component is electrically connected with a chassis via the body when installed.

2. The bracket according to claim 1, wherein a reinforced edge angled with respect to the body is disposed on the top of the body.

3. The bracket according to claim 1, wherein the body is provided with a plurality of openings and a plurality of conductive components, and each of the plurality of openings is corresponding to each of the plurality of conductive components.

4. The bracket according to claim 1, wherein the conductive component is substantially in a shape of Z, one end of the conductive component is connected to the body above the opening, and the other end of the conductive component is used for being electrically connected with the housing of the interface adapter.

5. The bracket according to claim 1, wherein one end of the body is provided with an add-in card fixing element, and the add-in card fixing element and the conductive component are disposed on the same side of the body for fixing the bracket to the add-in card.

6. The bracket according to claim 1, wherein one end of the body is provided with a chassis fixing element, and the chassis fixing element and the conductive component are disposed on opposite sides of the body for fixing the bracket to the chassis.

7. The bracket according to claim 1, wherein the conductive component is an elastic component so that the conductive component is configured to elastically press against the housing of the interface adapter in the installed state.

8. An add-in card system of an electronic device, comprising:
an add-in card provided with an interface adapter;
a bracket coupled to one end of the add-in card, the bracket including:
a body in a shape of a sheet, wherein the body is provided with an opening, the opening corresponding to the interface adapter of the add-in card and exposing an interface part of the interface adapter; and
a conductive component in electrical connection with the body, the conductive component electrically connected with a housing of the interface adapter, wherein at least a portion of the body is made of a conductive material so that the conductive component is electrically connected with a chassis of an electronic device via the body.

9. The add-in card system according to claim 8, wherein a reinforced edge angled with respect to the body is disposed on the top of the body.

10. The add-in card system according to claim 8, wherein the body is provided with a plurality of openings and a plurality of conductive components, and each of the plurality of openings is corresponding to each of the plurality of conductive components.

11. The add-in card system according to claim 8, wherein the conductive component is substantially in a shape of Z, one end of the conductive component is connected to the body above the opening, and the other end of the conductive component is electrically connected with the housing of the interface adapter.

12. The add-in card system according to claim 8, wherein one end of the body is provided with an add-in card fixing element, the add-in card fixing element and the conductive component are disposed on the same side of the body, and the bracket is fixed to the add-in card through the add-in card fixing element.

13. The add-in card system according to claim 8, wherein one end of the body is provided with a chassis fixing element, and the chassis fixing element and the conductive component are disposed on the opposite sides of the body for fixing the bracket to the chassis.

14. The add-in card system according to claim 8, wherein the conductive component is an elastic component so that the conductive component elastically presses against the housing of the interface adapter.

15. The add-in card system according to claim 8, wherein a flexible conductive enhancing element is disposed between the conductive component and the housing of the interface adapter.

16. A computer, comprising:
a chassis with an add-in card installing port provided thereon;
an add-in card provided with an interface adapter; and
a bracket coupled to one end of the add-in card, the add-in card installed to the chassis through the bracket and the add-in card installing port is covered by the bracket, the bracket including:
a body in a shape of a sheet, wherein the body is provided with an opening, the opening corresponding to the interface adapter of the add-in card and exposing an interface part of the interface adapter; and
a conductive component in electrical connection with the body, the conductive component electrically connected with a housing of the interface adapter, wherein at least a portion of the body is made of a conductive material so that the conductive component is electrically connected with a chassis of an electronic device via the body.

17. The computer according to claim 16, wherein the conductive component is substantially in a shape of Z, one end of the conductive component is connected to the body above the opening, and the other end of the conductive component is electrically connected with the housing of the interface adapter.

18. The computer according to claim 16, wherein one end of the body is provided with an add-in card fixing element and a chassis fixing element, the add-in card fixing element and the conductive component are disposed on the same side of the body, the bracket is fixed to the add-in card through the add-in card fixing element, and the chassis fixing element and the conductive component are disposed on the opposite sides of the body, and the bracket is fixed to the chassis through the chassis fixing element.

19. The computer according to claim 16, wherein the conductive component is an elastic component so that the conductive component elastically presses against the housing of the interface adapter.

20. The computer according to claim 16, wherein a flexible conductive enhancing element is disposed between the conductive component and the housing of the interface adapter.
